(19) United States
(12) Patent Application Publication
(10) Pub. No.: US 2008/0094561 A1
(43) Pub. Date: Apr. 24, 2008

(54) SYSTEM FOR PROVIDING A FLAT DISPLAY PANEL

(76) Inventors: Chih-Shun Fan, Hsinchu County (TW); Norio Oku, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/550,804

(22) Filed: Oct. 19, 2006

(51) Int. Cl. G02F 1/1345; G02F 1/1333

(52) U.S. Cl. 349/151; 349/158

(57) ABSTRACT

A system for providing a flat display panel is provided. A representative system includes a bottom substrate and a top substrate. The bottom substrate has an active region and a periphery region adjacent to the active region, and the bottom substrate has at least a truncated corner region in the periphery region. The top substrate is positioned on the bottom substrate, and overlaps the active region of the bottom substrate.

### BACKGROUND OF THE INVENTION

1. Field of the Invention

The invention relates to a system for providing a flat display panel.

2. Description of the Prior Art

With reference to FIG. 1 and FIG. 2, the top glass substrate 12 and the bottom glass substrate 14 are two rectangles in the top view. The bottom glass substrate 14 has four corner regions 14a, 14b, 14c, 14d, and each corner region of the two substrates 12, 14 has a right angle in the contours. The top glass substrate 12 has a smaller size than that of the bottom glass substrate 14. Accordingly, a portion of the bottom glass substrate 14 covered by the top glass substrate 12 is defined as an active region 18, and another portion of the bottom glass substrate 14 is an uncovered region, defined as a periphery region 20.

The active region 18 includes a pixel array region 11 and a control circuit region 13. The periphery region 20 has a plurality of periphery circuits and conducting pads 22 for electrically connecting to external circuits and sending signals through internal circuits of the flat display panel 10, such as voltage lines or scan control signal lines.

A top view of the flat display panel 10 after a conventional drop test is illustrated in FIG. 3. As shown in FIG. 3, the flat display panel 10 is dropped from a predetermined height to the ground so as to test the reliability of the flat display panel 10. When the flat display panel 10 falls to the ground, the flat display panel 10 is stricken suddenly by an impulsive force, and probably cracks thereafter.

Since the periphery region 20 of the bottom glass substrate 14 is not covered by the top glass substrate 12, the structural breakages 28 often occur in the periphery region 20 of the bottom glass substrate 14. The corner regions 14a, 14b with right angles are especially easily broken under such stresses or forces. Once the corner regions 14a, 14b are broken, it leads to some crushed glass, and the crushed glass sequentially scratches and caves in the components of the flat display panel 10. The unexpected structural breakages 28 may even damage the periphery circuits directly, or extend from the periphery region 20 to the active region 18, damaging the pixel array region 11 and the control circuit region 13.

As a result, all components in the flat display panel 10 are unavoidably damaged. Once the periphery circuits in the periphery region 20 are broken, electrical connections between the external circuits and the internal circuits are destroyed. If the pixel array region 11 or the control circuit region 13 is broken, the flat display panel 10 becomes an inferior product under its visual effect.

Accordingly, it is still an important issue for the manufacturer of displays to provide a flat display panel that has reliable structure to avoid the structural breakages under external stresses or forces in the uncovered periphery circuit region.

### SUMMARY OF THE INVENTION

System for providing a flat display panel is provided.

An embodiment of such a system comprises a flat display panel. The flat display panel includes a bottom substrate and a top substrate. The bottom substrate has an active region and a periphery region adjacent to the active region, and the bottom substrate has at least a truncated corner region in the periphery region. The top substrate is positioned on the bottom substrate, and overlaps the active region of the bottom substrate.

These and other aspects of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a top view of a flat display panel according to the prior art.

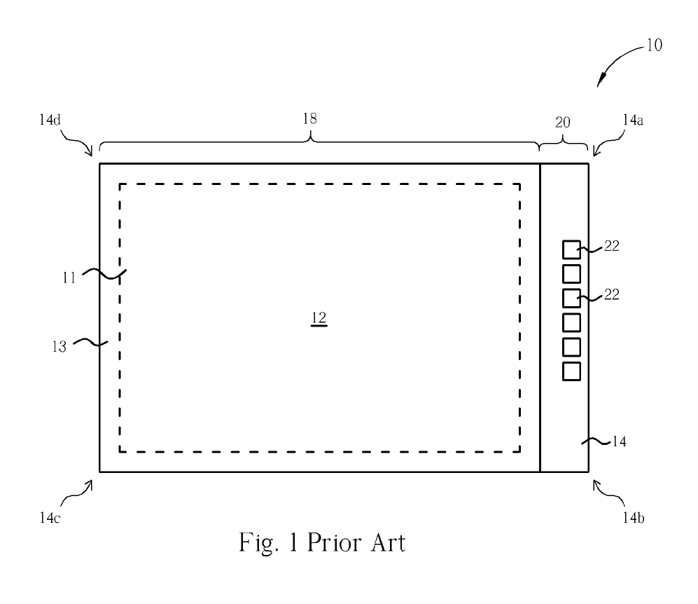

FIG. 2 is a side view of the flat display panel shown in FIG. 1.

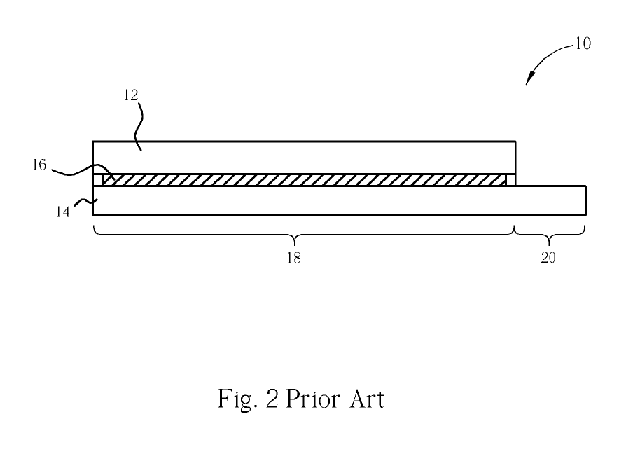

FIG. 3 illustrates a top view of the flat display panel shown in FIG. 1 undergoing a conventional drop test.

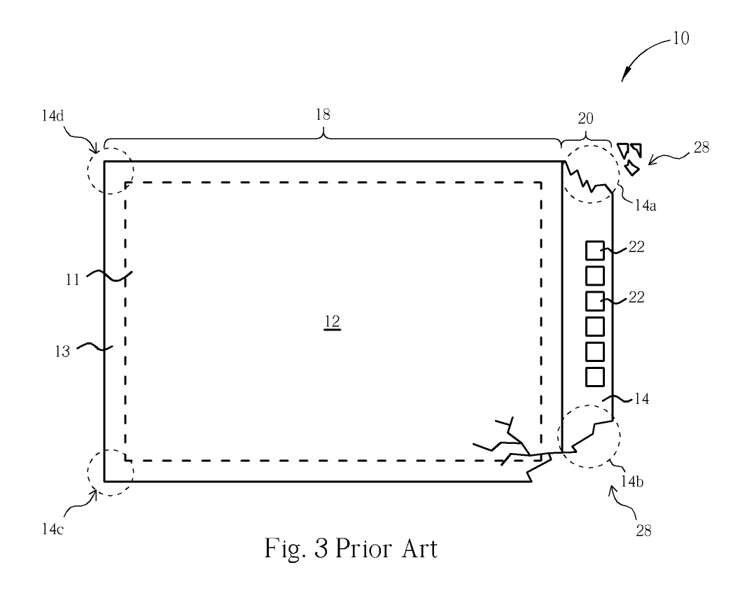

FIG. 4 is a block diagram a system for providing a flat display panel, implemented here as of an electronic device comprising the flat display panel according to one embodiment of the present invention.

FIG. 5 is a schematic diagram illustrating parts of the flat display panel shown in FIG. 4.

FIG. 6 is a schematic diagram illustrating parts of a flat display panel according to another embodiment of the present invention.

FIG. 7 is a schematic diagram of a flat display panel according to another embodiment of the present invention.

### DETAILED DESCRIPTION

The present invention is directed to a system with flat display panel that has a bottom substrate, wherein the bottom substrate has at least a truncated corner region. The truncated corner region prevents the flat display panel from being damaged in the drop test or an unexpected fall.

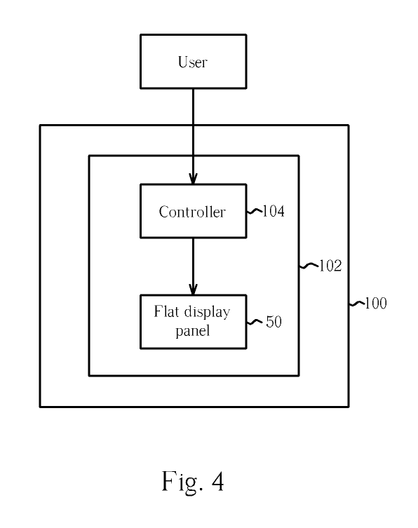

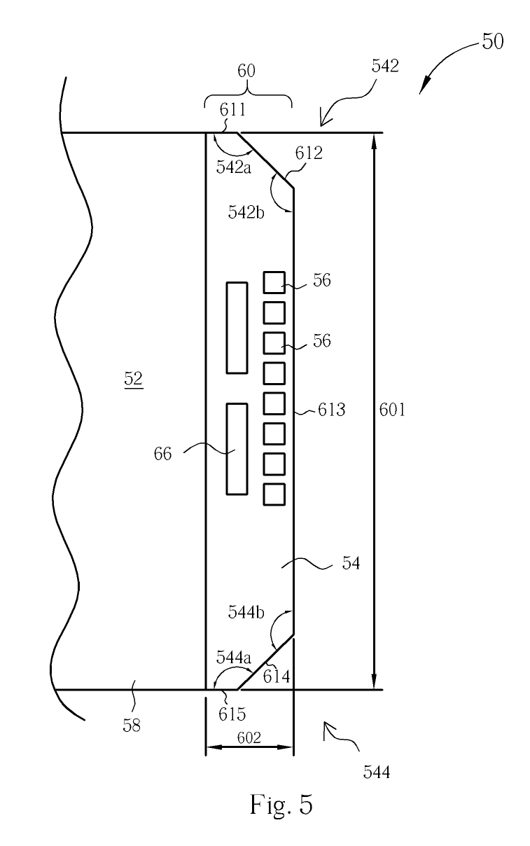

With reference to FIGS. 4-5, FIG. 4 is a block diagram of a system for providing a flat display panel, implemented here as an electronic device 100 comprising the flat display panel 50 according to a first embodiment of the present invention. As shown in FIG. 4, the electronic device 1 00 comprises a display device 102, such as an LCD device, and the display device 102 comprises a controller 104 and the flat display panel 50, wherein the controller 104 is coupled to the flat display panel 50 and can be operative to control the flat display panel 50 to render images in accordance with input signals. The electronic device 100 may be a laptop computer, a mobile phone, a digital camera, a personal digital assistant (PDA), a desktop computer, a television, a car display, a music player or a portable digital versatile disc (DVD) player. Therefore, a user may control the electronic device 100 through the controller 104 to operate the flat display panel 50.

As shown in FIG. 5, the flat display panel 50 comprises a top substrate 52 and a bottom substrate 54. A portion of the bottom substrate 54 is an uncovered region defined as a periphery region 60 while the portion of the bottom substrate 54 covered by the top substrate 52 is defined as an active region 58. According to various embodiments of the present invention, the display panel 50 can be applied to an LCD, an organic light emitting diode (OLED) display, a field emission display (FED), a plasma display panel (PDP), or a surface-conduction electron-emitter display (SED).

The active region 58 can include a pixel array region and a control circuit region (not shown in the figure). The periphery region 60 comprises a plurality of conducting pads 56 and at least an integrated circuit (IC) chip 66 on the bottom substrate 54.

The periphery region 60 is substantially a rectangular in top view, but the two corner regions 542, 544 of the bottom substrate 54 are truncated. Specifically, the corner regions 542, 544 of the peripheral region 60 are truncated diagonally. The truncated corner region 542 includes three side surfaces 611, 612, 61 3, where the side surfaces 611, 613 are perpendicular to each other, and the side surface 612 is diagonal with respect to the side surfaces 611, 613. Accordingly, the side surface 612 and the side surfaces 611, 613 form two obtuse angles 542a, 542b. On the other hand, the truncated corner region 544 includes three side surfaces 613, 614, 615, where the side surfaces 613, 615 are perpendicular to each other, and the side surface 614 is diagonal with respect to the side surfaces 613, 615. Thus, the side surface 614 and the side surfaces 613, 615 form two obtuse angles 544a, 544b. The strength of the bottom substrate 54 is greatly affected by the magnitude of these angles. In practice, the obtuse angles 542a, 542b, 544a, 544b can be in a range of 95° to 175°. Since the corner regions 542, 544 are no longer in sharp shapes, the flat display panel 50 has a tougher structure.

Generally, a corner region in an obtuse angle is structurally tougher than a corner region in a right angle. As a result, the structural breakages in the bottom substrate 54 can be avoided, and the reliability of the flat display panel 50 is effectively increased. In addition, the flat display panel 50 with the truncated corner region takes less space, so the flat display panel 50 may reserve more space for other components.

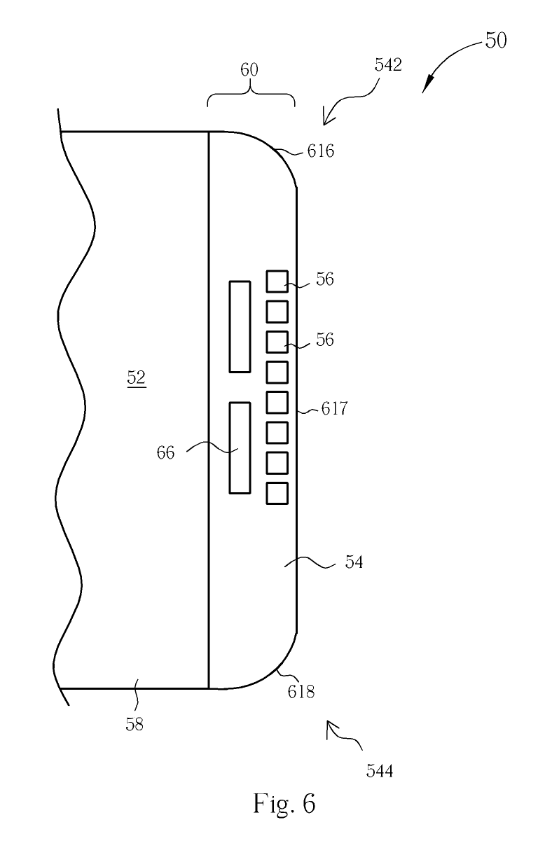

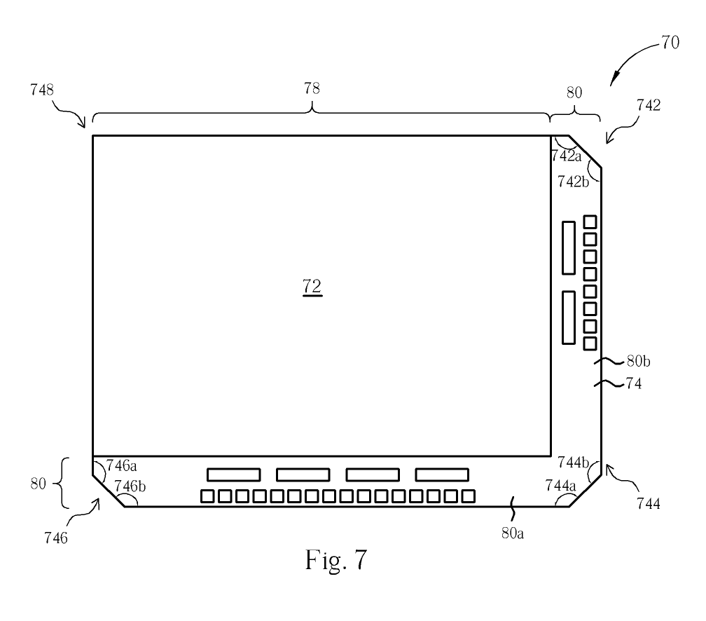

The peripheral region 60 has a substantial width 601, which is also a width of the flat display panel 50, and a substantial length 602. It should be noted that the shape in the top-view of the flat display panel 50 is not limited to the shape shown in FIG. 5. Any bottom substrate having at least a truncated corner region may be included. Accordingly, the contour of the periphery region 60 (depending on the lengths of the side surfaces 611, 612, 613, 614, 615, and the magnitudes of the angles 542a, 542b, 544a, 544b) could be adjusted according to the ratio of the periphery region's length 602 to width 601, the ratio of the periphery region's length 602 to the active region's length (not shown in the figure), the periphery region's length 602, width 601, and thickness (not shown in the figure), etc. FIG. 6 and FIG. 7 are schematic diagrams of flat display panels 50, 70 according to other embodiments of the present invention respectively. Most of the numerals of elements in FIG. 6 are the same as that in FIG. 5 for simplifying explanation.

As shown in FIG. 6, the bottom substrate 54 has four corner regions 542, 544, 546, 548. The corner region 542 includes two side surfaces 616, 617, and the corner region 544 includes two side surfaces 617, 618. The side surfaces 616, 618 are rounded surfaces, while the side surface 617 is a plane surface. Accordingly, corner regions 542, 544 can be two arc corner regions in top view. Since the corner regions 542, 544 are no longer in sharp shapes in top view, the corner regions 542, 544 are structurally tougher. In various embodiments, the corner regions 542, 544 of the periphery region 60 could even be formed in an octagon, a polygon, etc.

As shown in FIG. 7, the portion of the bottom substrate 74 covered by the top substrate 72 is defined as an active region 78 while the portion of the bottom substrate 74 not covered by the top substrate 72 is defined as a periphery region 80. For the flat display panel 70, the periphery region 80 includes two periphery parts 80a, 80b. The two periphery parts 80a, 80b are individually extended from two sides of the active region 78, while the two sides of the active region 78 are adjacent to each other. Thereafter, the periphery region 80 can be substantially an L-shape region in top view, so as to include more components in the periphery region 80.

The bottom substrate 74 has four corner regions 742, 744, 746, 748, and the corner regions 742, 744, 746 can be truncated. Each of the truncated corner regions 742, 744, 746 includes three side surfaces, and the three side surfaces form two obtuse angles. There are obtuse angles 742a, 742b in the corner region 742, obtuse angles 744a and 744b in the corner region 744, and obtuse angles 746a, 746b in the corner region 746. In practice, the obtuse angles 742a, 742b, 744a, 744b, 746a, 746b can be in a range of 95° to 175°. Since the corner regions 742, 744, 746 are no longer in sharp shapes, the flat display panel 70 has a tougher structure.

Noticing that the shape of the flat display panel is not limited to the shape shown in the above-mentioned embodiments, the shape of the flat display panel can be adjusted for any specification of a product. It should be understood by one skilled in the art that small chamfers may be further included on any edge of the top or the bottom substrate. The chamfers make edges of the top or the bottom substrate smoother.

Because a right-angled corner region of the periphery region is the easiest-broken portion of an electronic device including a flat display panel, the periphery region having at least a blunt corner region is structurally tougher. Thus, the strength of the bottom substrate is enhanced by the truncated corner region, the occurring probability of the structural breakage in the periphery region is effectively decreased, and the reliability of the electronic device is therefore increased. Furthermore, the problem of crushed glass causing a broken substrate is also avoided, so the flat display panel is no longer scratched and caved in by this crushed glass.

Besides, the flat display panel with the truncated corner region takes less space than the flat display panel with the right-angled corner region. The space can make the electronic device in an embodiment of the present invention have more capacity for holding other components, so the electronic device can have more variety.

Those skilled in the art will readily observe that numerous modifications and alterations of the device and method may be made while retaining the teachings of the invention. Accordingly, the above disclosure should be construed as limited only by the metes and bounds of the appended claims.

1. A system for providing a flat display panel comprising:
a bottom substrate comprising an active region and a periphery region adjacent to the active region, the bottom substrate comprising a plurality of corner regions in the periphery region; and
a top substrate positioned on the bottom substrate, overlapping the active region of the bottom substrate, each of the said corner regions, which is not covered by the top substrate, being a truncated corner region.

2. The system as claimed in claim 1, wherein the truncated corner region comprises three side surfaces, two of the side surfaces are perpendicular to each other, and diagonal with respect to the other side surface.

3. The system as claimed in claim 2, wherein the three side surfaces form two obtuse angles.

4. The system as claimed in claim 1, wherein the truncated corner region comprises two included angles, and at least one of the included angles is in a range of 95° to 175°.

5. The system as claimed in claim 1, wherein the periphery region is substantially a rectangular region.

6. The system as claimed in claim 1, wherein the bottom substrate comprises two the truncated corner regions in the periphery region.

7. The system as claimed in claim 6, wherein each of the truncated corner regions comprises three side surfaces, two of the side surfaces are perpendicular to each other, and diagonal with respect to the other side surface in each of the truncated corner regions.

8. The system as claimed in claim 7, wherein the three side surfaces form two obtuse angles in each of the truncated corner regions.

9. The system as claimed in claim 6, wherein each of the truncated corner regions comprises two included angles, and at least one of the included angles is in a range of 95° to 175°.

10. The system as claimed in claim 1, wherein the periphery region is extended from two sides of the active region.

11. The system as claimed in claim 10, wherein the two sides of the active region are adjacent to each other, and the periphery region is substantially an L-shape region.

12. The system as claimed in claim 11, wherein the bottom substrate comprises three the truncated corner regions in the periphery region.

13. The system as claimed in claim 12, wherein each of the truncated corner regions comprises two obtuse angles.

14. The system as claimed in claim 12, wherein each of the truncated corner regions comprises two included angles, and at least one of the included angles is in a range of 95° to 175°.

15. The system as claimed in claim 1, wherein the system further comprises:
a display device comprising the flat display panel; and
a controller coupled to the flat display panel, the controller being operative to control the flat display panel to render images in accordance with input signals.

16. The system as claimed in claim 15, wherein the system further comprises an electronic device comprising the display device, and the electronic device is a laptop computer, a mobile phone, a digital camera, a personal digital assistant (PDA), a desktop computer, a television, a car display, a music player or a portable DVD player.
